(19) United States
(12) Patent Application Publication
(10) Pub. No.: US 2025/0210568 A1
(43) Pub. Date: Jun. 26, 2025

(54) REDISTRIBUTION LAYER STRUCTURE FOR HIGH-DENSITY SEMICONDUCTOR PACKAGE ASSEMBLY

(71) Applicant: MEDIATEK INC., Hsinchu City (TW)

(72) Inventors: Yi-Jou LIN, Hsinchu City (TW); Tsai-Ming LAI, Hsinchu City (TW); I-Hsuan PENG, Hsinchu City (TW); Wei-Chen CHANG, Hsinchu City (TW); Laurene YIP, San Jose, CA (US)

(21) Appl. No.: 18/849,138

(22) PCT Filed: Mar. 17, 2023
(86) PCT No.: PCT/CN2023/082276

§ 371 Date: Sep. 20, 2024

Related U.S. Application Data
(60) Provisional application No. 63/323,590, filed on Mar. 25, 2022.

(51) Int. Cl. H01L 23/00

(52) U.S. Cl. CPC H01L 24/24; H01L 2224/2405; H01L 2224/24101; H01L 2224/244

(57) ABSTRACT

A redistribution layer (RDL) structure for a semiconductor package assembly is provided. The RDL structure includes a via and a first conductive trace connected to the via. The first conductive trace includes a first segment and a second segment. The first segment is disposed away from the via and extends along a first direction. The second segment is disposed close to the via and connected to the first segment. The second segment extends along a second direction. A width of the first conductive trace is stepwise increased toward the via.

### CROSS REFERENCE TO RELATED APPLICATIONS

This application claims the benefit of U.S. Provisional Application No. 63/323,590, filed Mar. 25, 2022, the entirety of which is incorporated by reference herein.

### TECHNICAL FIELD

The present invention relates to a redistribution layer (RDL) structure for a semiconductor package assembly and a semiconductor package assembly, and, in particular, to a design of conductive traces of a redistribution layer (RDL) structure for a semiconductor package assembly.

### BACKGROUND

The continuous drive for higher compute power and greater data bandwidth to meet the growing data demands from data centers, networking, and artificial intelligence has driven the development of advanced packaging solutions for higher performance devices.

Among the advanced packaging technologies, wafer level fan-out has emerged as an attractive package solution for heterogeneous integration. Wafer level fan-out, which uses fine-pitch redistribution layer (RDL) technology for die interconnection, can enable the development of high-performance products with large package footprint, and high interconnect density. However, package reliability is becoming a critical concern as the overall die size and package size increase to accommodate the integration of more chiplets for networking and high-performance applications. As the die size increases, the package stress also increases due to the coefficient of thermal expansion (CTE) mismatch between the die and the substrate and increases the risk for package failures caused by bump cracks, mold compound delamination, and RDL failures in the fan-out package.

Thus, a novel RDL structure for a semiconductor package assembly is desirable.

### SUMMARY

An embodiment of the present invention provides a redistribution layer (RDL) structure for a semiconductor package assembly. The RDL structure includes a via and a first conductive trace connected to the via. The first conductive trace includes a first segment and a second segment. The first segment is disposed away from the via and extends along a first direction. The second segment is disposed close to the via and connected to the first segment. The second segment extends along a second direction. A width of the first conductive trace is stepwise increased toward the via. An embodiment of the present invention provides a semiconductor package assembly. The semiconductor package assembly includes a semiconductor die and a redistribution layer (RDL) structure. The RDL structure is electrically connected to the semiconductor die. The RDL structure includes a via and a conductive trace connected to the via. The conductive trace includes a first line-shaped segment, a second line-shaped segment and a bending segment. The first line-shaped segment is disposed away from the via and has a first width. The second line-shaped segment is disposed close to the via and has a second width that is greater than the first width. The bending segment is connected between the first line-shaped segment and the second line-shaped segment.

In addition, an embodiment of the present invention provides a semiconductor package assembly. The semiconductor package assembly includes a redistribution layer (RDL) structure, a first semiconductor die and a second semiconductor die. The RDL structure includes a via and a V-shaped conductive trace. The V-shaped conductive trace is connected to the via. A width of the V-shaped conductive trace is stepwise increased toward via. The first semiconductor die is disposed on the RDL structure. The first semiconductor die includes a first interface. The second semiconductor die is disposed on the RDL structure and beside the first semiconductor die. The second semiconductor die includes a second interface. The first interface is electrically connected to the second interface by the RDL structure.

### BRIEF DESCRIPTION OF THE DRAWINGS

The present invention can be more fully understood by reading the subsequent detailed description and examples with references made to the accompanying drawings, wherein:

FIG. 1 is a cross-sectional view of a semiconductor package assembly in accordance with some embodiments of the disclosure;

FIG. 2 is an enlarged view of FIG. 1, showing a portion of a redistribution layer (RDL) structure of a fan-out package in accordance with some embodiments of the disclosure;

FIG. 3 is a schematic bottom view of the fan-out package of a semiconductor package assembly in accordance with some embodiments of the disclosure, showing the arrangement of interfaces (the interface floorplan) of semiconductor dies in the fan-out package; and

FIG. 4 is a top view of a portion of a redistribution layer (RDL) structure of the fan-out package in accordance with some embodiments of the disclosure.

### DETAILED DESCRIPTION

The following description is made for the purpose of illustrating the general principles of the invention and should not be taken in a limiting sense. The scope of the invention is best determined by reference to the appended claims.

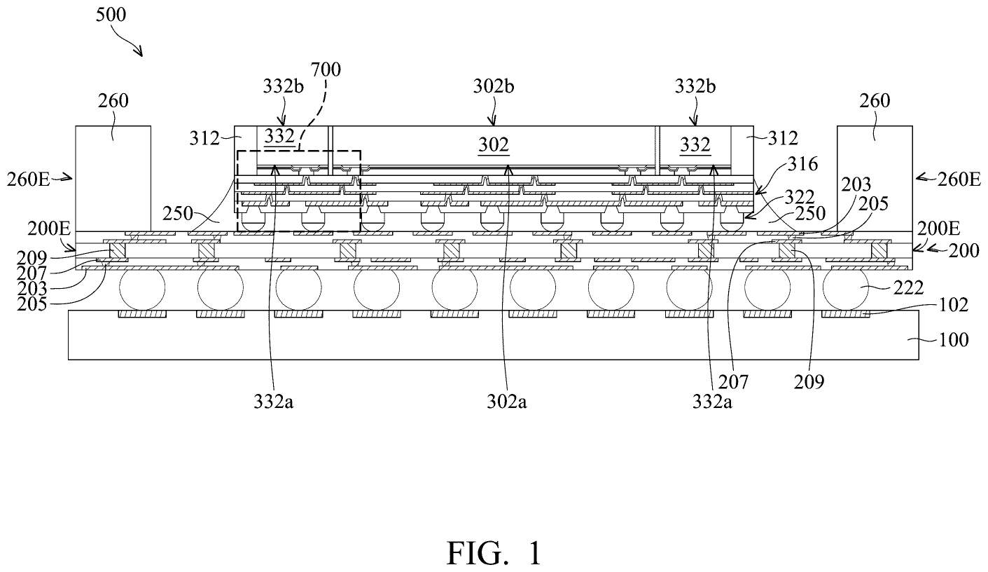

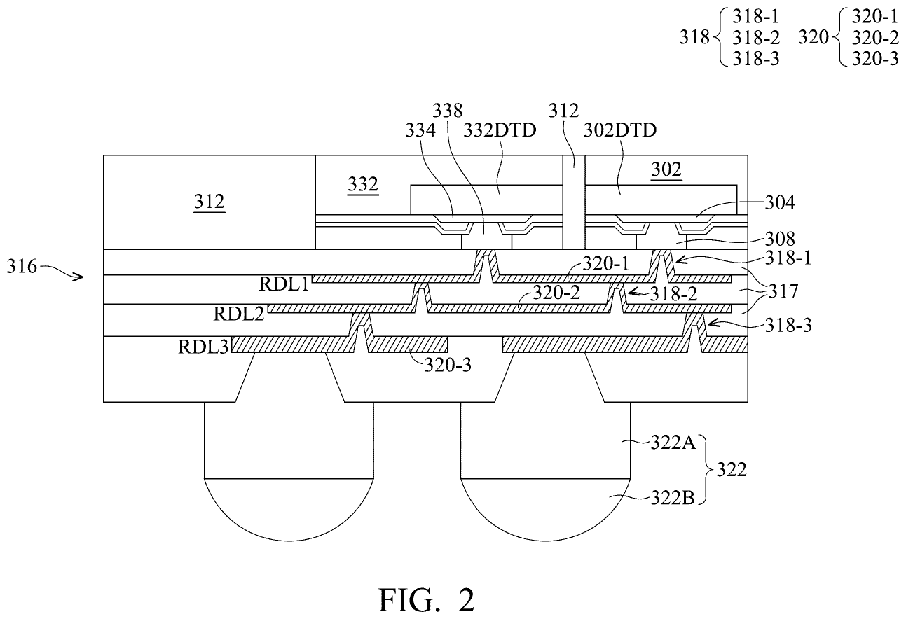

FIG. 1 is a cross-sectional view of a semiconductor package assembly 500 in accordance with some embodiments of the disclosure. FIG. 2 is an enlarged cross-sectional view of FIG. 1, showing a portion of a redistribution layer (RDL) structure 316 of a fan-out package 300 in accordance with some embodiments of the disclosure. In some embodiments, the semiconductor package assembly 500 can be used to form a fan-out package, a two-dimensional (2D) package, 2.5D a 2.5D package, a three-dimensional (3D) semiconductor package, or another suitable package. The semiconductor package assembly 500 may include at least one wafer-level fan-out package 300 mounted on a substrate 200. In addition, the substrate 200 is mounted on a base 100.

As shown in FIG. 1, the base 100, for example a printed circuit board (PCB), may be formed of polypropylene (PP). It should also be noted that the base 100 can be a single layer or a multilayer structure. A plurality of pads 102 and/or conductive traces (not shown) is disposed on the base 100. In some embodiments, the conductive traces include signal trace segments or ground trace segments, which are used for the input/output (I/O) connections of the fan-out package 300. Also, the fan-out package 300 is mounted directly on the conductive traces. In some other embodiments, the pads 102 are disposed on the base 100, connected to different terminals of the conductive traces. The pads 102 are used for the semiconductor package 100 that is mounted directly on them.

As shown in FIG. 1, the substrate 200 may serve as a fan-out structure for the overlying fan-out package 300. In some embodiments, the substrate 200 includes a core substrate or a coreless substrate. In some embodiments, the substrate 200 includes one or more conductive routings disposed therein. In some embodiments, the conductive routings includes one or more conductive pads 203, conductive vias 205, conductive traces 207 and conductive pillars 209 disposed in one or more dielectric layers (not shown). In some embodiments, the conductive pads 203, the conductive vias 205, the conductive traces 207 and the conductive pillars 209 include a conductive material, such as metals comprising copper, gold, silver, or other applicable metals. In some embodiments, the dielectric layers may be formed of organic materials, which include a polymer base material, non-organic materials, which include silicon nitride (SiNₓ), silicon oxide (SiOₓ), grapheme, or the like. For example, the dielectric layers are made of a polymer base material. However, it should be noted that the number and configuration of the dielectric layers, the conductive pads 203, the conductive vias 205, the conductive traces 207 and the conductive pillars 209 shown in FIG. 1 are only an example and is not a limitation to the present invention.

As shown in FIG. 1, conductive structures 222 are disposed between the substrate 200 and the base 100. The conductive structures 222 are disposed on the substrate 200 away from the semiconductor package 100 and in contact with the conductive pads 203 of the substrate 200 and the corresponding contact pads 110 of the base 100. Therefore, the substrate 200 is electrically connected to the base 100 via the conductive structures 222. In some embodiments, the conductive structures 222 comprise a conductive ball structure such as a copper ball, a conductive bump structure such as a copper bump or a solder bump structure, or a conductive pillar structure such as a copper pillar structure.

As shown in FIGS. 1 and 2, the fan-out package 300 (also called the system-on-chip (SOC) package 300a) is mounted on the substrate 200 opposite the conductive structures 222 by a bonding process using conductive structures 322. The fan-out package 300 includes semiconductor dies 302 and 332, a molding compound 312, the redistribution layer (RDL) structure 316 and the conductive structures 322. The conductive structures 322 are in contact with and electrically connected to the RDL structure 316 and the conductive pads 203 of the substrate 200. In some embodiments, the conductive structures 322 comprise a conductive ball structure such as a copper ball, a conductive bump structure such as a copper bump or a solder bump structure, or a conductive pillar structure such as a copper pillar structure. For example, the conductive structures 322 may be controlled collapse chip connection (C4) structures composed of conductive pillar structures 322A and conductive bump structures 322B.

Since single advanced node system on chip (SOC), can no longer meet the increasing demands of high-performance computing (HPC) applications, there is a growing trend to use a chiplet architecture approach to split a large, monolithic semiconductor die into multiple smaller functional blocks (also called chiplets) and re-integrating the chiplet using advanced packaging technology. The chiplet architecture not only can bring the different functional blocks closer to each other to improve device performance but also can improve fabrication yields of the individual semiconductor dies and help reduce the overall fabrication cost. In some embodiments, the fan-out package 300 includes semiconductor dies, for example, the semiconductor die 302 and the semiconductor dies 332 arranged side-by-side as shown in FIG. 1. The first semiconductor die 302 has an active surface 302a and a backside surface 302b opposite to the active surface 302a. The second semiconductor die 332 has an active surface 332a and a backside surface 332b opposite to the active surface 332a. In some embodiments, the semiconductor dies 302 and 332 are fabricated by a flip-chip technology and flipped to be disposed on the RDL structure 316 opposite the conductive structures 322. In some embodiments, the semiconductor dies 302 and 332 each independently includes a system-on-chip (SoC) die, a logic device, a memory device, a radio frequency (RF) device, the like, or any combination thereof. For example, the semiconductor dies 302 and 332 may each independently include a micro control unit (MCU) die, a microprocessor unit (MPU) die, a power management integrated circuit (PMIC) die, a global positioning system (GPS) device, a central processing unit (CPU) die, a graphics processing unit (GPU) die, an input/output (I/O) die, a dynamic random access memory (DRAM) IP core, a static random-access memory (SRAM), a high bandwidth memory (HBM), the like, or any combination thereof. In some embodiments, the semiconductor dies 302 and 332 have different functions.

As shown in FIGS. 1 and 2, the RDL structure 316 is disposed on the active surface 302a of the semiconductor die 302 and the active surfaces 332a of the semiconductor dies 332. In other words, the semiconductor dies 302 and 332 are disposed on the RDL structure 316. In addition, the RDL structure 316 is disposed between the semiconductor die 302, the semiconductor dies 332 and the substrate 200. Pads 304 and 334 disposed on the active surfaces 302a and 332a of the semiconductor dies 302 and 332 are in contact with the corresponding vias 308 and 338. The semiconductor dies 302 and 332 are connected to the RDL structure 316 by the vias 308 and 338 without using micro bumps or underfill between the semiconductor dies 302 and 332 and the RDL structure 316. In addition, the conductive structures 322 are electrically connected to the semiconductor dies 302 and 332 by the RDL structure 316.

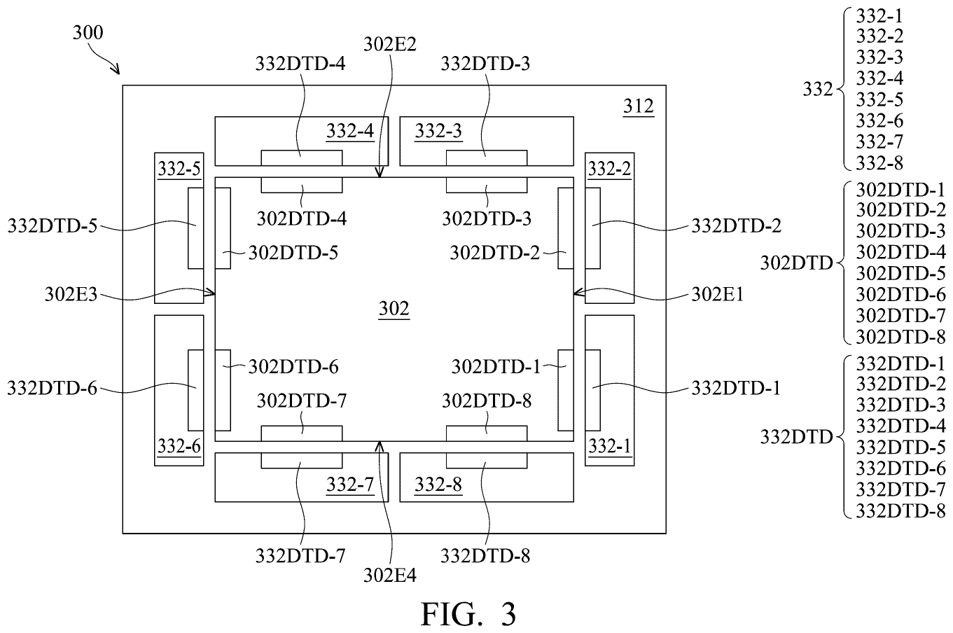

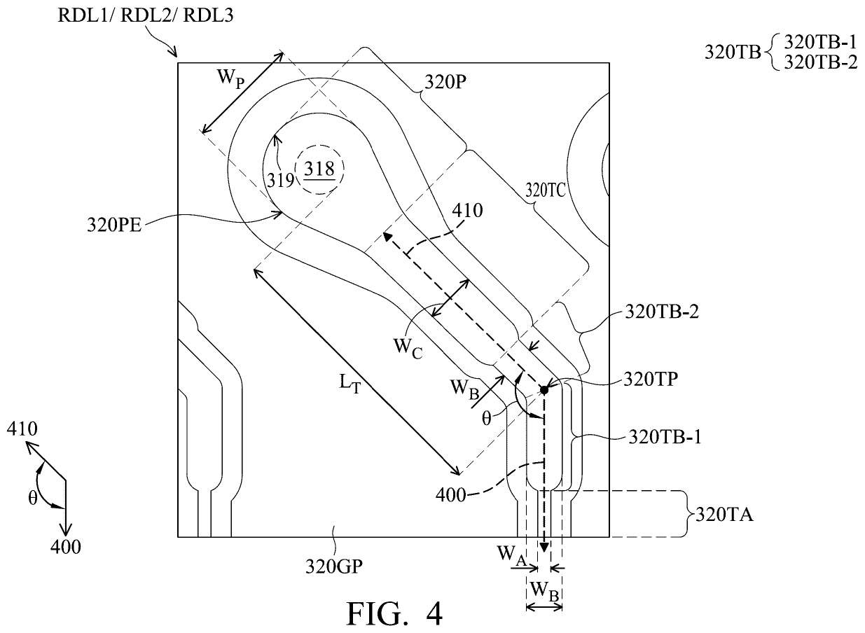

In some embodiments, the RDL structure 316 may include one or more RDL layers (e.g. RDL layers RDL1, RDL2 and RDL3 shown in FIG. 2) alternatively arranged with one or more dielectric layers 317. The RDL layers RDL1, RDL2 and RDL3 include ground plates (e.g., a ground plate 320GP shown in FIG. 4), conductive traces 320 (including conductive traces 320-1, 320-2 and 320-3 at different levels) and one or more vias 318 (including vias 318-1, 318-2 and 318-3) disposed in one or more dielectric layers 317. In some embodiments, the ground plates are grounded and connected to ground pads of the semiconductor dies 302 and 332. The conductive traces 320-1, 320-2 and 320-3 may be used for transmitting signal and connected to signal pads of the semiconductor dies 302 and 332. In addition, top surfaces of the ground plates and the conductive traces belong to the same RDL layers may be substantially coplanar with each other. The vias 318-1, 318-2 and 318-3 are electrically connected to the semiconductor dies 302 and 332 and the conductive traces 320-1, 320-2 and 320-3 at different levels. For example, the semiconductor die 332 is electrically connected to the conductive trace 320-1 by the via 318-1. The conductive trace 320-1 is electrically connected to the conductive trace 320-2 by the via 318-2. The conductive trace 320-2 is electrically connected to the conductive trace 320-3 by the via 318-3. In some embodiments, the semiconductor die 302 is electrically connected to the adjacent semiconductor dies 332 only using the vias 318 and the conductive traces 320 inside the RDL structure 316. In some embodiments, the conductive traces 320 and the vias 318 include a conductive material, such as metals comprising copper, gold, silver, or other applicable metals. The dielectric layers 317 may include extra-low K (ELK) dielectrics and/or ultra-low K (ULK) dielectric. In addition, the dielectric layers 317 may include epoxy. The semiconductor dies 302 and 332 are electrically connected to the substrate 200 using the vias 318 and the conductive traces 320 of the RDL structure 316 and the corresponding conductive structures 322. It should be noted that the number of RDL layers RDL1, RDL2 and RDL3, the number of vias 318, the number of conductive traces 320 and the number of dielectric layers 317 shown in FIGS. 1 and 3 are only an example and is not a limitation to the present invention.

As shown in FIGS. 1 and 2, the molding compound 312 is disposed on and in contact with the RDL structure 316. In addition, the molding compound 312 surrounds and is in contact with the semiconductor dies 302 and 332. The backside surface 302b of the semiconductor die 302 and the backside surfaces 332b of the semiconductor dies 132 may be exposed from the molding compound 312. In some embodiments, the molding compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the semiconductor dies 302 and 332, and then may be cured using a UV or thermally curing process. The molding compound 312 may be cured with a mold (not shown).

As shown in FIG. 1, the semiconductor package assembly 500 further includes an underfill 250 filling a gap (not shown) between the RDL structure 316 and the substrate 200. In some embodiments, the underfill 250 surrounds a portion of the molding material 312, the RDL structure 316 and the conductive structures 322 and is in contact with a portion of the substrate 200 to further reduce the thermal resistance from the fan-out package 300 to the substrate 200. In addition, the underfill 250 may be disposed to compensate for differing coefficients of thermal expansion (CTEs) between the semiconductor dies 302 and 332, the RDL structure 316, the conductive structures 322 and the substrate 200. In some embodiments, the underfill 250 includes a capillary underfill (CUF), a molded underfill (MUF), or a combination thereof.

As shown in FIG. 1, the semiconductor package assembly 500 further includes a stiffener ring 260 mounted on the substrate 200 opposite the conductive structures 222 222 using an adhesive layer (not shown). The stiffener ring 260 may be adhered onto the substrate 200 along edges 200E of the substrate 200. The semiconductor dies 302 and 332 are surrounded by the stiffener ring 260. The stiffener ring 260 is used for warpage control to reduce the high stress experienced by bonded various materials in the semiconductor package assembly during cycles of heating and cooling. The stiffener ring 260 may provide extra support to the semiconductor package assembly 500 thus reducing warpage. In some embodiments, the stiffener ring 260 are separated from the underfill 250 by a gap (not shown). In some embodiments, edges 260E of the stiffener ring 260 are leveled with the corresponding edges 200E of the substrate 200. Therefore, the edges 260E of the stiffener ring 260 and the edges 200E of the substrate 200 may collectively serve as edges of the semiconductor package assembly 500. In some embodiments, the stiffener ring 260 includes metals, such as copper.

FIG. 3 is a schematic bottom view of the fan-out package 300 of a semiconductor package assembly 500 in accordance with some embodiments of the disclosure, showing the arrangement of interfaces (the interface floorplan) of semiconductor dies 302 and 332 in the fan-out package 300. In some embodiments, the interfaces of the fan-out package 300 used herein may include circuitry and input/output connections (e.g. the pads 304 and 334) disposed on the active surfaces 302a and 332a of the semiconductor dies 302 and 332. In some embodiments, the interfaces of the semiconductor dies 302 and 332 are used for signal transmission (data transmission) between the different semiconductor dies 302 and 332 of the same fan-out package 300. It is noted that FIG. 3 only show the semiconductor dies 302 and 332 and the molding material 312 of the fan-out package 300 for illustration, the remaining features may be shown in the schematic cross-sectional views of FIGS. 1 and 2.

As shown in FIG. 3, in the fan-out package 300, the semiconductor die 302 (e.g., the SOC die) is electrically connected to and surrounded by eight identical semiconductor dies 332 (e.g. input/output (I/O) dies). In this embodiments, the semiconductor dies 332 include semiconductor dies 332-1, 332-2, 332-3, 332-4, 332-5, 332-6, 332-7 and 332-8. In some embodiments, the semiconductor dies 302 and 332 may include interfaces arranged on edges of the semiconductor die 302 and adjacent edges of the semiconductor dies 332 for internal electrical connections between the different semiconductor dies of the same the fan-out package 300 of the semiconductor package assembly 500.

For example, the semiconductor die 302 may include interfaces 302DTD (including interfaces 302DTD-1, 302DTD-2, 302DTD-3, 302DTD-4, 302DTD-5, 302DTD-6, 302DTD-7 and 302DTD-8) arranged on edges 302E1, 302E2, 302E3 and 302E4 of the semiconductor die 302. The semiconductor dies 332-1 and 332-2 are arranged side-by side and close to the edge 302E1 of the semiconductor die 302. The semiconductor dies 332-3 and 332-4 are arranged side-by side and close to the edge 302E2 of the semiconductor die 302. The semiconductor dies 332-5 and 332-6 are arranged side-by side and close to the edge 302E3 of the semiconductor die 302. The semiconductor dies 332-7 and 332-8 are arranged side-by side and close to the edge 302E1 of the semiconductor die 302. In addition, the semiconductor dies 332 may include interfaces 332DTD (including interfaces 332DTD-1, 332DTD-2, 332DTD-3, 332DTD-4, 332DTD-5, 332DTD-6, 332DTD-7 and 332DTD-8) close to the corresponding interfaces 302DTD-1, 302DTD-2, 302DTD-3, 302DTD-4, 302DTD-5, 302DTD-6, 302DTD-7 and 302DTD-8 of the semiconductor die 302. In some embodiments, the interfaces 302DTD-1, 302DTD-2, 302DTD-3, 302DTD-4, 302DTD-5, 302DTD-6, 302DTD-7, 302DTD-8, 332DTD-1, 332DTD-2, 332 DTD-3, 332 DTD-4, 332DTD-5, 332DTD-6, 332DTD-7 and 332DTD-8 are die-to-die (DTD) interfaces including any suitable direct conductive electrical coupling between two different semiconductor dies 302 and 332 for data transmission. In some embodiments, the interfaces 302DTD-1, 302DTD-2, 302DTD-3, 302DTD-4, 302DTD-5, 302DTD-6, 302DTD-7, 302DTD-8 of the semiconductor die 302 are electrically connected to the corresponding interfaces 302DTD-1, 302DTD-2, 302DTD-3, 302DTD-4, 302DTD-5, 302DTD-6, 302DTD-7 and 302DTD-8 of the semiconductor die 332 by the RDL structure 316.

Because the semiconductor dies 302 and 332 and the molding compound 312 are disposed on the RDL structure 316 of the semiconductor package assembly 500, the RDL structure 316 may suffer the stress produced from the semiconductor dies 302 and 332 and the molding compound 312. Also, the RDL structure 316 may suffer the stress due to the mismatch of thermal expansion of the coefficient (CTE) between the RDL structure 316 and the semiconductor dies 302 and 332, between the RDL structure 300 and the molding compound 312, and between the semiconductor dies 302 and 332 and the molding compound 312. The CTE mismatch issue between different materials in the semiconductor package assembly 500 can cause the warpage issue and induce mechanical stresses that can cause RDL trace (e.g., the conductive traces 320) cracking and other failures in the semiconductor package assembly 500. Also, the RDL structure 316 in regions corresponding to the DTD interfaces (e.g., the interfaces 302DTD and 302DTD) of the semiconductor dies 302 and 332 may experience high stress due to the high density of the conductive traces 320 and the vias 318. Moreover, the bend portions of the conductive trace 320 may suffer significant stresses, which can lead to cracking of the conductive trace 320. In order to reduce the stress applied to the RDL structure 316, the dimensions and geometries of the conductive traces 320 may be optimized as follows.

FIG. 4 is a top view of a portion of the RDL structure 316 of the fan-out package 300 in accordance with some embodiments of the disclosure, showing the arrangement of the RDL layers at respective levels. In some embodiments, the RDL layer (e.g., the RDL layer RDL1, RDL2 or RDL3) of the RDL structure 316 includes the ground plate 320GP, the conductive trace 320 and the via 318. The ground plate 320GP may include one or more openings 319 for one or more conductive traces 320 extending through. In addition, the opening 319 is filled with the dielectric layer 317 shown in FIGS. 1 and 2. The conductive trace 320 is connected to the corresponding via 318.

As shown in FIG. 4, the conductive trace 320 close to the corresponding via 318 may have a V-shape and include segments 320TA, 320TB (including portions 320TB-1 and 320TB-2) and 320TC and a pad portion 320P. In some embodiments, the segment 320TA is disposed away from the via 318 and extends along a direction 400. The segment 320TC is disposed close to the via 318 and extends along a direction 410 that is different from direction 400. The pad portion 320P covers the via 318 and connected to the segment 320TC. In addition, the segment 320TA is connected to the segment 320TC through the segment 320TB.

In some embodiments, widths of the segments 320TA, 320TB and 320TC of the conductive trace 320 is stepwise increased toward the via 318 to reduce the risk of cracking of the conductive trace 320. As shown in FIG. 4, the segments 320TA and 320TC may be both line-shaped segments (also called line-shaped segments 320TA and 320TC) and have different widths W_{A} and W_{C}. It is noted that the width of the different segments of the conductive trace 320 herein refers to the distance between opposite sidewalls of the segment in a direction perpendicular to the extending direction (e.g., the direction 400 or 410) of the segment. In some embodiments, the width W_{A} of the segment 320TA has a uniform value. For example, the width W_{A} may be equal to the minimum width of the metal line of the RDL structure 316 of the design rule. In some embodiments, the width W_{C} of the segment 320TC has a uniform value and is greater than the width W_{A}. For example, the width W_{C} is in a range from about 25% to about 125% greater than the width W_{A}. If the width W_{C} is less than 25% greater than the width W_{A}, the RDL structure 316 may still suffer high stress. If the width W_{C} is more than 125% greater than the width W_{A}, the RDL structure 316 may suffer the reduced routing density.

In some embodiments, the segment 320TB is a bending segment (also called the bending segment 320TB) connected between the segments 320TA and 320TC. Two ends (not shown) of the segment 320TB are in contact with the segments 320TA and 320TC. In addition, the portion 320TB-1 is connected to the segment 320TA and extends along the direction 400, and the portion 320TB-2 is connected between is connected to the segment 320TA and the segment 320TC and extends along the direction 410. In some embodiments, the bending segment 320TB has a width W_{B} of a uniform value that is different from the width W_{A}. For example, the width W_{B} may be in a range from about 25% to about 125% greater than the width W_{A}. If the width W_{B} is less than 25% greater than the width W_{A}, the RDL structure 316 may still suffer high stress. If the width W_{B} is more than 125% greater than the width W_{A}, the RDL structure 316 may suffer the reduced routing density. In some embodiments, the width W_{B} is different from the width W_{C}. For example, the width W_{B} may be greater than the width W_{A} and less than the width W_{C}. In some other embodiments, the width W_{B} is equal to the width W_{C} and greater than the width W_{A}.

In some embodiments, a bend angle of the bending segment 320TB may be an obtuse angle to maintain the bending segment 320TB in a uniform width, so that the stress on the conductive trace 320 can be further reduced. In some embodiments, the bending segment 320TB has a bend angle θ (also called an included angle θ between the portions 320TB-1 and 320TB-2) in a range from about 135 degrees to about 150 degrees. Therefore, an angle (equal to the bend angle θ) between the segment 320TA extending along the direction 400 and the segment 320TC extending along the direction 410 is between about 135 degrees and 150 degrees. If the bend angle θ is less than 135 degrees, the bending segment 320TB may suffer high stress and cause the RDL cracking issue. If the bend angle θ is greater than 150 degrees, the routing density of the RDL structure 316 may be reduced.

In some embodiments, the distance of the portion of the conductive trace 320 between the via 318 and the turning point of the bending segment 320TB may be increased to release the stress applied to the bending segment 320TB. As shown in FIG. 4, the pad portion 320P directly over the via 318 is connected to and in contact with the segment 320TC opposite the segment 320TA. The pad portion 320P may have a teardrop-shape in a top view as shown in FIG. 4. In addition, an edge 320PE of the pad portion 320P may enclose the via 318 in the top view as shown in FIG. 4. In some embodiments, the pad portion 320P has a diameter W_{P} greater than the widths W_{A}, W_{B} and W_{C}. It is noted that the diameter W_{P} of the pad portion 320P of the conductive trace 320 herein refers to the distance between opposite sidewalls of the pad portion 320P in a direction perpendicular to the extending direction (i.e., the direction 410) of the segment 320TC connected to the pad portion 320P. In some embodiments, a ratio of a length LT of a portion of the conductive trace 320 between the via 318 and a turning point 320TP of the bending segment 320TB to the diameter W_{P} of the pad portion 320P is greater than 1.66 in order to reduce the stress concentration of the bending segment 320TB of the conductive trace 320. If the ratio of the length LT to the diameter W_{P} is less than 1.66, the stress applied to the pad portion 320P may increase the stress concentration at the bending segment 320TB.

Embodiments provide a semiconductor package assembly, for example, a fan-out wafer-level semiconductor package (FOWLP). The semiconductor package assembly includes a redistribution layer (RDL) structure to redistribute and fan-out one or more of the die pads with a small pitch. The conductive trace of the RDL structure may include a pad portion covering the corresponding via and segments having respective uniform widths connected to the pad portion. The respective widths of the segments are designed to be stepwise increased toward the via to reduce the risk of cracking of the conductive trace. In some embodiments, the segments of the conductive trace include at least two line-shaped segments and a bending segment connected between the two line-shaped segments extending in different directions. The bend angle of the bending segment is designed to be between 135 degrees and 150 degrees, reducing the amount of stress applied to the bending segment while increasing the routing density. In some embodiments, the distance between the via and the turning point of the bending segment of the conductive trace is designed to be 1.66 times larger than the diameter of the pad portion to further release the stress applied to the bending segment of the conductive trace. According to the design of the conductive trace of the RDL structure, the problem of cracks forming in areas in the RDL structure corresponding to the interfaces of the semiconductor dies can be avoided. In addition, the RDL stress effects can be minimized, enabling the large format fan-out packages to be more reliable.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A redistribution layer (RDL) structure for a semiconductor package assembly, comprising:
a via; and
a first conductive trace connected to the via, wherein the first conductive trace comprises:
a first segment away from the via and extending along a first direction; and
a second segment close to the via and connected to the first segment, wherein the second segment extends along a second direction,
wherein a width of the first conductive trace is stepwise increased toward the via.

2. The RDL structure for a semiconductor package assembly as claimed in claim 1, wherein an angle between the first segment and the second segment is in a range from about 135 degrees to about 150 degrees.

3. The RDL structure for a semiconductor package assembly as claimed in claim 1, wherein the first conductive trace further comprises:
a bending segment connected between the first segment and the second segment, wherein the first portion has a first width, and the second portion has a second width, and wherein the bending segment has a third width different from the first width and the second width.

4. The RDL structure for a semiconductor package assembly as claimed in claim 3, wherein the first width is equal to a minimum width of a metal line of the RDL structure of the design rule.

5. The RDL structure for a semiconductor package assembly as claimed in claim 3, wherein the second width and the third width are in a range from about 25% to about 125% greater than the first width.

6. The RDL structure for a semiconductor package assembly as claimed in claim 3, wherein the third width is greater than the first width and less than the second width.

7. The RDL structure for a semiconductor package assembly as claimed in claim 3, wherein the first conductive trace comprises:
a pad portion covering the via and connected to the second segment, wherein a ratio of a length of a portion of the first conductive trace between the via and a turning point of the bending segment to a diameter of the pad portion is greater than 1.66.

8. The RDL structure for a semiconductor package assembly as claimed in claim 1, further comprising:
a second conductive trace disposed at a second level and electrically connected to the first conductive trace at a first level by the via.

9. A semiconductor package assembly, comprising:
a semiconductor die; and
a redistribution layer (RDL) structure electrically connected to the semiconductor die, wherein the RDL structure comprises:
a via; and
a conductive trace connected to the via, wherein the conductive trace comprises:
a first line-shaped segment away from the via and having a first width;
a second line-shaped segment close to the via and having a second width greater than the first width; and
a bending segment connected between the first line-shaped segment and the second line-shaped segment.

10. The semiconductor package assembly as claimed in claim 9, wherein the first width is equal to a minimum width of a metal line of the design rule.

11. The semiconductor package assembly as claimed in claim 9, wherein the bending segment has a bend angle in a range from about 135 degrees to about 150 degrees.

12. The semiconductor package assembly as claimed in claim 9, wherein the bending segment has a third width greater than the first width and less than the second width.

13. The semiconductor package assembly as claimed in claim 12, wherein the third width is in a range from about 25% to about 125% greater than the first width, and the second width is in a range from about 25% to about 125% greater than the first width.

14. The semiconductor package assembly as claimed in claim 9, wherein the conductive trace comprises:
a pad portion covering the via and in contact with the second line-shaped segment opposite the first line-shaped segment, wherein a ratio of a length of a portion of the conductive trace between the via and a turning point of the bending segment to a diameter of the pad portion is greater than 1.66.

15. A semiconductor package assembly, comprising:
a redistribution layer (RDL) structure, wherein the RDL structure comprises:
a via; and
a V-shaped conductive trace connected to the via, wherein a width of the V-shaped conductive trace is stepwise increased toward the via;
a first semiconductor die disposed on the RDL structure, wherein the first semiconductor die comprises a first interface; and
a second semiconductor die disposed on the RDL structure and beside the first semiconductor die, wherein the second semiconductor die comprises a second interface, and wherein the first interface is electrically connected to the second interface by the RDL structure.

16. The semiconductor package assembly as claimed in claim 15, wherein the V-shaped conductive trace has an included angle in a range from about 135 degrees to about 150 degrees.

17. The semiconductor package assembly as claimed in claim 15, wherein the V-shaped conductive trace comprises:
a pad portion covering the via;
a first line-shaped segment away from the via and having a first width;
a second line-shaped segment in contact with the pad portion and having a second width greater than the first width; and
a bending segment connected between the first line-shaped segment and the second line-shaped segment and having a third width greater than the first width and less than the second width.

18. The semiconductor package assembly as claimed in claim 17, wherein the second width and the third width are in a range from about 25% to about 125% greater than the first width.

19. The semiconductor package assembly as claimed in claim 17, wherein a ratio of a length of a portion of the V-shaped conductive trace between the via and a turning point of the bending segment to a diameter of the pad portion is greater than 1.66.

20. The semiconductor package assembly as claimed in claim 15, further comprising:
a conductive structure disposed on the RDL structure and opposite the first semiconductor die and the second semiconductor die, wherein the conductive structure is electrically connected to the first semiconductor die and the second semiconductor die by the RDL structure.
